(19) United States
(12) Patent Application Publication
(10) Pub. No.: US 2026/0342049 A1
(43) Pub. Date: Oct. 29, 2026

(54) SEMICONDUCTOR LIGHT EMITTING DEVICE

(71) Applicant: ROHM CO., LTD., Kyoto-shi (JP)

(72) Inventor: Keiji HIDAKA, Kyoto-shi (JP)

(21) Appl. No.: 19/704,618

(22) Filed: Jun. 11, 2026

Related U.S. Application Data
(63) Continuation of application No. PCT/JP2024/044009, filed on Dec. 12, 2024.

(30) Foreign Application Priority Data
Dec. 18, 2023 (JP) 2023-212851

(51) Int. Cl. H01S 5/22

(52) U.S. Cl. CPC H01S 5/2202

(57) ABSTRACT

A semiconductor light emitting device includes a substrate, a semiconductor layer, an insulating film, and a metal layer. The semiconductor layer is disposed on the substrate. A first groove and a second groove that penetrate the semiconductor layer to expose the substrate are formed in the semiconductor layer. In a plan view, the first groove and the second groove extend along a first direction and are spaced apart from each other along a second direction perpendicular to the first direction. The semiconductor layer between the first groove and the second groove forms a mesa structure serving as a light emitting portion. The insulating film is disposed on the substrate exposed from the first groove and the second groove, on side walls of the first groove, on side walls of the second groove, and on the semiconductor layer.

### TECHNICAL FIELD

The present disclosure relates to a semiconductor light emitting device.

### BACKGROUND ART

For example, Japanese Patent Laying-Open No. 2023-100967 (PTL 1) describes a semiconductor light emitting device. The semiconductor light emitting device described in PTL 1 has a substrate, a semiconductor layer, an insulating film, and a metal layer.

The semiconductor layer is disposed on the substrate. A first groove and a second groove are formed in the semiconductor layer. In a plan view, the first groove and the second groove extend along a first direction and are spaced apart from each other along a second direction orthogonal to the first direction. The first groove and the second groove penetrate the semiconductor layer. In other words, the substrate is exposed from each of the first groove and the second groove. A portion of the semiconductor layer between the first groove and the second groove forms a mesa structure serving as a light emitting portion.

The semiconductor layer (mesa structure) has a light emitting layer and a contact layer. The light emitting layer has an n-type cladding layer, a p-type cladding layer, and an active layer. The active layer is disposed on the n-type cladding layer. The p-type cladding layer is disposed on the active layer. In other words, the active layer is sandwiched between the n-type cladding layer and the p-type cladding layer in the thickness direction of the semiconductor layer. The contact layer is disposed on the light emitting layer (p-type cladding layer).

The insulating film is disposed on the substrate exposed from each of the first groove and the second groove, on side walls of the first groove, on side walls of the second groove, and on the mesa structure. An opening is formed in a portion of the insulating film on the mesa structure. The opening penetrates the insulating film, and the mesa structure (contact layer) is exposed from the opening. The metal layer is disposed on the insulating film so as to be electrically connected to the mesa structure via the opening.

### CITATION LIST

### Patent Literature

PTL 1: Japanese Patent Laying-Open No. 2023-100967

### BRIEF DESCRIPTION OF DRAWINGS

FIG. 1 is a plan view of a semiconductor light emitting device 100.

FIG. 2 is a sectional view taken along the line II-II in FIG. 1.

FIG. 3 is a sectional view taken along the line III-III in FIG. 1.

FIG. 4 is an enlarged sectional view of a light emitting layer 21.

FIG. 5 is an enlarged sectional view of an active layer 21c.

FIG. 6 is an enlarged sectional view of a tunnel layer 23.

FIG. 7 is a schematic graph showing the relationship between a forward current flowing through a mesa structure 24 and an optical output in semiconductor light emitting device 100.

FIG. 8 is a diagram of a process for manufacturing semiconductor light emitting device 100.

FIG. 9 is a sectional view for illustrating a semiconductor layer formation step S2.

FIG. 10 is a sectional view for illustrating a groove formation step S3.

FIG. 11 is a sectional view for illustrating an insulating film formation step S4.

FIG. 12 is a sectional view for illustrating a first metal layer formation step S5.

FIG. 13 is a sectional view for illustrating a second metal layer formation step S6.

FIG. 14 is a plan view of a semiconductor light emitting device 100A.

FIG. 15 is a sectional view taken along the line XV-XV in FIG. 14.

FIG. 16 is a sectional view taken along the line XVI-XVI in FIG. 14.

FIG. 17 is a schematic graph showing the relationship between a forward current flowing through mesa structure 24 and an optical output in semiconductor light emitting device 100 and a semiconductor light emitting device 100A.

FIG. 18 is a plan view of a semiconductor light emitting device 200.

FIG. 19 is a sectional view for illustrating an insulating film formation step S4 in a method of manufacturing semiconductor light emitting device 200.

### DETAILED DESCRIPTION

Embodiments of the present disclosure will be described in detail with reference to the drawings. In the following drawings, the same or corresponding parts are denoted by the same reference signs, and redundant descriptions will not be repeated.

### Embodiment 1

A semiconductor light emitting device (semiconductor light emitting device 100) according to Embodiment 1 will be described.

### Configuration of Semiconductor Light Emitting Device 100

A configuration of semiconductor light emitting device 100 will be described below.

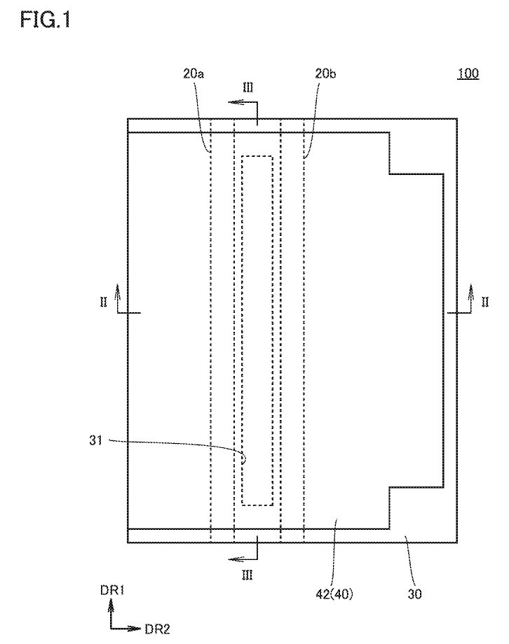

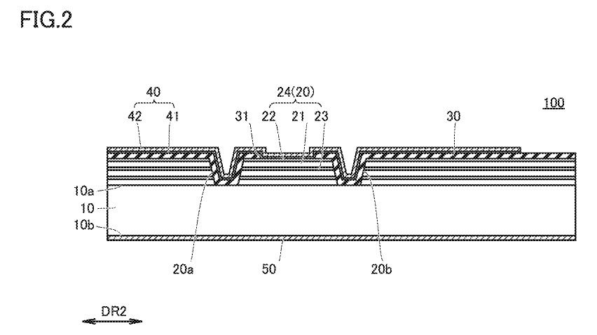

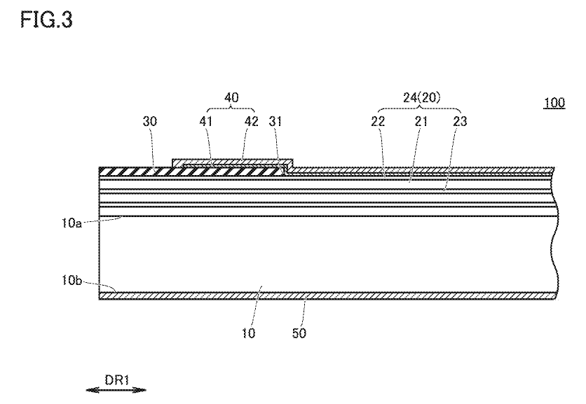

FIG. 1 is a plan view of semiconductor light emitting device 100. FIG. 2 is a sectional view taken along the line II-II in FIG. 1. FIG. 3 is a sectional view taken along the line III-III in FIG. 1. As shown in FIGS. 1, 2, and 3, semiconductor light emitting device 100 includes a substrate 10, a semiconductor layer 20, an insulating film 30, a metal layer 40, and a metal layer 50.

A constituent material of substrate 10 is a semiconductor material. The constituent material of substrate 10 is, for example, gallium arsenide (GaAs). The conductivity type of substrate 10 is, for example, an n type. Substrate 10 has a main surface 10a and a main surface 10b. Main surface 10b is opposite to main surface 10a. Main surface 10a and main surface 10b are end surfaces of substrate 10 in the thickness direction.

Semiconductor layer 20 is disposed on substrate 10. More specifically, semiconductor layer 20 is disposed on main surface 10a. Semiconductor layer 20 is epitaxially grown on substrate 10 (main surface 10a). Semiconductor layer 20 includes at least one light emitting layer 21 and a contact layer 22. In the examples shown in FIGS. 1 to 3, the number of the light emitting layers 21 is three. When a plurality of light emitting layers 21 are provided, the plurality of light emitting layers 21 are stacked along the thickness direction of semiconductor layer 20. In this case, semiconductor layer 20 further includes a tunnel layer 23. Tunnel layer 23 is disposed between two adjacent light emitting layers 21.

Contact layer 22 is disposed on the uppermost light emitting layer 21. The constituent material of contact layer 22 is, for example, gallium arsenide. The constituent material of contact layer 22 is doped with a p-type impurity.

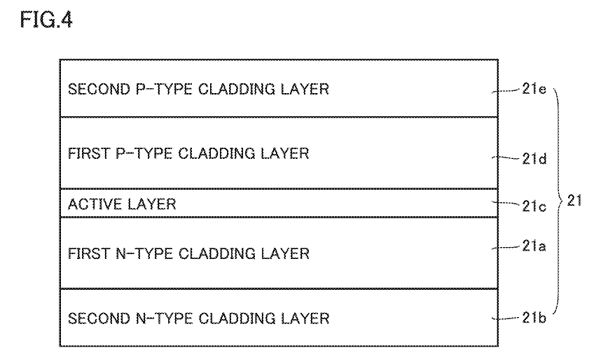

FIG. 4 is an enlarged sectional view of light emitting layer 21. As shown in FIG. 4, light emitting layer 21 includes, for example, a first n-type cladding layer 21a, a second n-type cladding layer 21b, an active layer 21c, a first p-type cladding layer 21d, and a second p-type cladding layer 21e. First n-type cladding layer 21a is disposed on second n-type cladding layer 21b. Active layer 21c is disposed on first n-type cladding layer 21a. First p-type cladding layer 21d is disposed on active layer 21c. Second p-type cladding layer 21e is disposed on first p-type cladding layer 21d. From another viewpoint, active layer 21c is sandwiched between first n-type cladding layer 21a and first p-type cladding layer 21d, and this three-layer structure is sandwiched between second n-type cladding layer 21b and second p-type cladding layer 21e.

Constituent materials of first n-type cladding layer 21a, second n-type cladding layer 21b, first p-type cladding layer 21d, and second p-type cladding layer 21e are, for example, aluminum gallium arsenide (AlGaAs). The composition of aluminum gallium arsenide is represented as Al_{X}Ga_{(1-X)}As. The value of X in first n-type cladding layer 21a is smaller than the value of X in second n-type cladding layer 21b. The value of X in first p-type cladding layer 21d is smaller than the value of X in second p-type cladding layer 21e.

The value of X in first n-type cladding layer 21a is, for example, 0.3 or more and 0.4 or less. The value of X in second n-type cladding layer 21b is, for example, 0.5 or more and 0.6 or less. The value of X in first p-type cladding layer 21d is, for example, 0.3 or more and 0.4 or less. The value of X in second p-type cladding layer 21e is, for example, 0.5 or more and 0.6 or less.

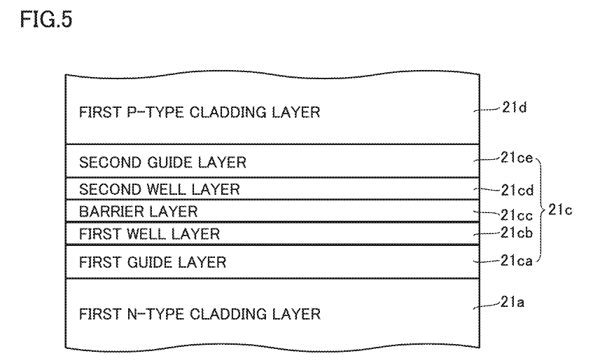

FIG. 5 is an enlarged sectional view of active layer 21c. As shown in FIG. 5, active layer 21c includes, for example, a first guide layer 21ca, a first well layer 21cb, a barrier layer 21cc, a second well layer 21cd, and a second guide layer 21ce. First guide layer 21ca is disposed on first n-type cladding layer 21a. First well layer 21cb is disposed on first guide layer 21ca. Barrier layer 21cc is disposed on first well layer 21cb. Second well layer 21cd is disposed on barrier layer 21cc. Second guide layer 21ce is disposed on second well layer 21cd. First p-type cladding layer 21d is disposed on second guide layer 21ce.

From another viewpoint, barrier layer 21cc is sandwiched between first well layer 21cb and second well layer 21cd, and this three-layer structure is sandwiched between first guide layer 21ca and second guide layer 21ce.

Constituent materials of first guide layer 21ca and second guide layer 21ce are, for example, aluminum gallium arsenide. For example, the value of X in first guide layer 21ca is smaller than the value of X in first n-type cladding layer 21a, and the value of X in second guide layer 21ce is smaller than the value of X in first p-type cladding layer 21d. The value of X in first guide layer 21ca and the value of X in second guide layer 21cd are, for example, 0.05 or more and 0.15 or less.

The constituent material of barrier layer 21cc is, for example, aluminum gallium arsenide. The value of X in barrier layer 21cc is, for example, smaller than the value of X in first n-type cladding layer 21a (the value of X in second guide layer 21ce). The value of X in barrier layer 21cc is, for example, 0.05 or more and 0.15 or less. Constituent materials of first well layer 21cb and second well layer 21cd are, for example, indium gallium arsenide (InGaAs). The composition of indium gallium arsenide is represented as In_{Y}Ga_{(1-Y)}As. The value of Y in first well layer 21cb and the value of Y in second well layer 21cd are, for example, greater than 0 and 0.15 or less.

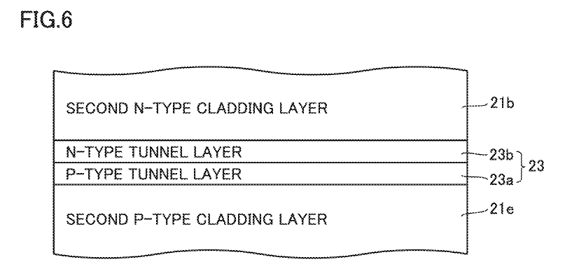

FIG. 6 is an enlarged sectional view of tunnel layer 23. As shown in FIG. 6, tunnel layer 23 includes a p-type tunnel layer 23a and an n-type tunnel layer 23b. P-type tunnel layer 23a is disposed on second p-type cladding layer 21e. N-type tunnel layer 23b is disposed on p-type tunnel layer 23a. Second n-type cladding layer 21b is disposed on n-type tunnel layer 23b. The constituent material of p-type tunnel layer 23a and the constituent material of n-type tunnel layer 23b are, for example, aluminum gallium arsenide. The constituent material of p-type tunnel layer 23a and the constituent material of n-type tunnel layer 23b are doped with a p-type impurity and an n-type impurity, respectively.

As shown in FIGS. 1, 2, and 3, a first groove 20a and a second groove 20b are formed in semiconductor layer 20. In a plan view, each of first groove 20a and second groove 20b extends along a first direction DR1. The end of first groove 20a in first direction DR1 and the end of second groove 20b in first direction DR1 reach the end of substrate 10 in first direction DR1.

Here, a plan view refers to a case where semiconductor light emitting device 100 is viewed along the normal direction of main surface 10a. Even if the extension direction of first groove 20a (the extension direction of second groove 20b) and first direction DR1 are not completely parallel to each other, if the angle formed by both directions is 5° or less, first groove 20a (second groove 20b) is considered to extend along first direction DR1.

In a plan view, first groove 20a and second groove 20b are provided side by side in a second direction DR2. Second direction DR2 is perpendicular to first direction DR1. Note that even if the direction in which first groove 20a and second groove 20b are provided side by side is not completely parallel to second direction DR2, if the angle formed by both directions is 5° or less, first groove 20a and second groove 20b are considered to be provided side by side along second direction DR2.

First groove 20a and second groove 20b penetrate semiconductor layer 20. In other words, substrate 10 (main surface 10a) is exposed from first groove 20a and second groove 20b. In a sectional view perpendicular to first direction DR1, the distance between a pair of side walls of first groove 20a and the distance between a pair of side walls of second groove 20b decrease as the grooves approach substrate 10.

A portion of semiconductor layer 20 between first groove 20a and second groove 20b forms a mesa structure 24. Mesa structure 24 serves as a light emitting portion of semiconductor light emitting device 100.

The constituent material of insulating film 30 is an insulating material. The constituent material of insulating film 30 is, for example, silicon nitride (SiN) or silicon oxide (SiO). Insulating film 30 is disposed on the side walls of first groove 20a, on the side walls of second groove 20b, on substrate 10 exposed from first groove 20a, on substrate 10 exposed from second groove 20b, and on semiconductor layer 20.

An opening 31 is formed in a portion of insulating film 30 on mesa structure 24. In a plan view, opening 31 extends along first direction DR1. However, it is preferable that the end of opening 31 in first direction DR1 does not reach the end of mesa structure 24 in first direction DR1 and is located inward of the end of mesa structure 24 in first direction DR1. Opening 31 penetrates insulating film 30 along the thickness direction. In other words, mesa structure 24 (contact layer 22) is exposed from opening 31.

Metal layer 40 is disposed on insulating film 30 so as to be electrically connected to mesa structure 24 (contact layer 22) via opening 31. Metal layer 40 includes a first layer 41 and a second layer 42. First layer 41 is disposed on insulating film 30. Furthermore, first layer 41 is also disposed on mesa structure 24 exposed from opening 31. Second layer 42 is disposed on first layer 41. However, the end of second layer 42 in first direction DR1 is disposed on insulating film 30.

The thickness of second layer 42 is, for example, larger than the thickness of first layer 41. First layer 41 is, for example, a vapor deposition layer. Second layer 42 is, for example, a plating layer. The constituent materials of first layer 41 and second layer 42 are conductive materials. The constituent materials of first layer 41 and second layer 42 are, for example, gold (Au). The end of first layer 41 in first direction DR1 is located inward of the end of second layer 42 in first direction DR1. The end of second layer 42 in first direction DR1 is, for example, located inward of the end of mesa structure 24 in first direction DR1.

The constituent material of metal layer 50 is a conductive material. The constituent material of metal layer 50 is, for example, gold. Metal layer 50 is disposed on main surface 10b. As a voltage is applied between metal layer 50 and metal layer 40 on mesa structure 24, a current is injected into mesa structure 24, generating laser light. The generated laser light is emitted from the end surface of mesa structure 24 in first direction DR1.

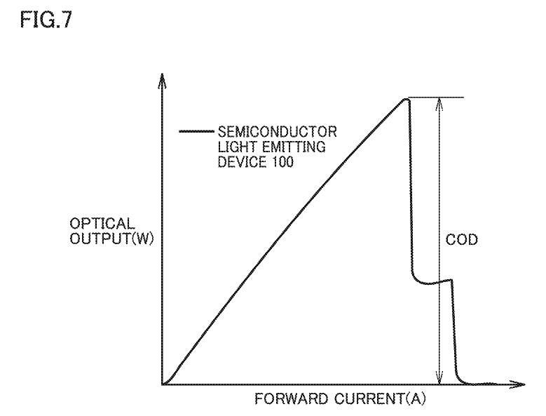

A value obtained by dividing the catastrophic optical damage (COD) of semiconductor light emitting device 100 by the width of mesa structure 24 in second direction DR2 is preferably 0.95 W/μm or more. Furthermore, the value obtained by dividing the COD of semiconductor light emitting device 100 by the width of mesa structure 24 in second direction DR2 is preferably 2.0 W/μm or less. FIG. 7 is a schematic graph showing the relationship between the forward current flowing through mesa structure 24 and the optical output in semiconductor light emitting device 100. The horizontal axis and vertical axis in FIG. 7 indicate the forward current (unit: A) and the optical output (unit: W), respectively. As shown in FIG. 7, as the forward current flowing through mesa structure 24 increases, the optical output increases. When the optical output reaches a peak, the optical output decreases sharply with the increase in the forward current flowing through mesa structure 24. The above-described peak of the optical output is defined as the COD of semiconductor light emitting device 100.

### Method of Manufacturing Semiconductor Light Emitting Device 100

A method of manufacturing semiconductor light emitting device 100 will be described below.

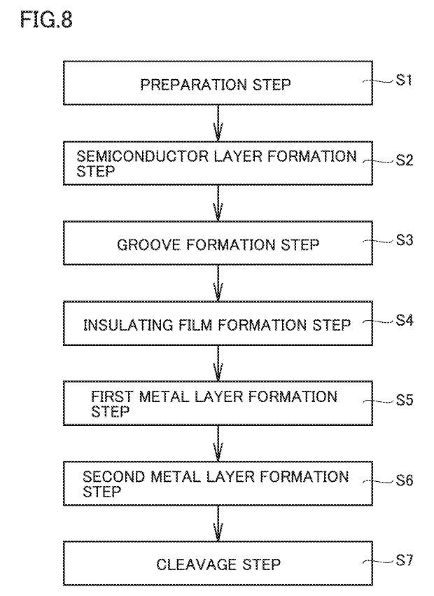

FIG. 8 is a diagram of a process for manufacturing semiconductor light emitting device 100. As shown in FIG. 8, the method of manufacturing semiconductor light emitting device 100 includes a preparation step S1, a semiconductor layer formation step S2, a groove formation step S3, an insulating film formation step S4, a first metal layer formation step S5, a second metal layer formation step S6, and a cleavage step S7.

In preparation step S1, substrate 10 is prepared. Semiconductor layer formation step S2 is performed after preparation step S1.

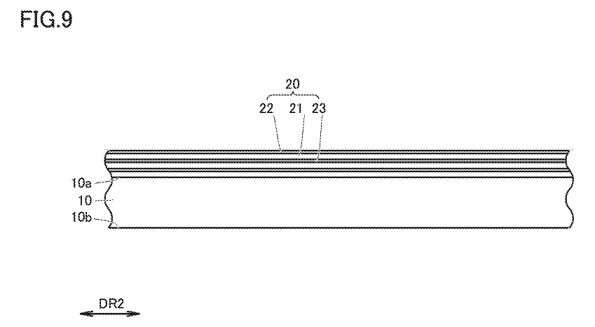

FIG. 9 is a sectional view for illustrating semiconductor layer formation step S2. As shown in FIG. 9, in semiconductor layer formation step S2, semiconductor layer 20 is epitaxially grown on substrate 10. Semiconductor layer 20 is formed by sequentially forming layers constituting semiconductor layer 20 by, for example, a chemical vapor deposition (CVD) method. Groove formation step S3 is performed after semiconductor layer formation step S2.

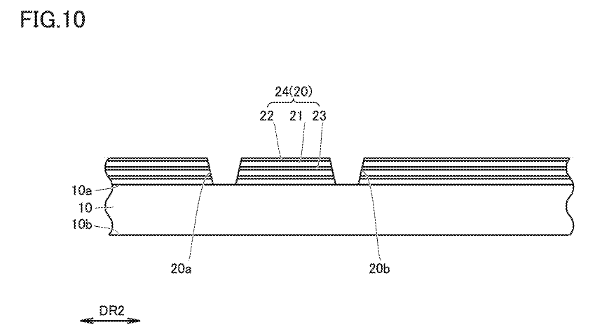

FIG. 10 is a sectional view for illustrating groove formation step S3. As shown in FIG. 10, in groove formation step S3, first groove 20a and second groove 20b are formed in semiconductor layer 20. In groove formation step S3, first, a resist pattern is formed on semiconductor layer 20. The resist pattern is formed by applying photoresist on semiconductor layer 20 and then exposing and developing the applied photoresist. Second, dry etching is performed on semiconductor layer 20 using the above-described resist pattern as a mask. Thus, first groove 20a and second groove 20b are formed. After the above-described dry etching, wet etching is performed on semiconductor layer 20, thereby removing damage introduced to the side walls of first groove 20a and the side walls of second groove 20b by the above-described dry etching. Insulating film formation step S4 is performed after groove formation step S3.

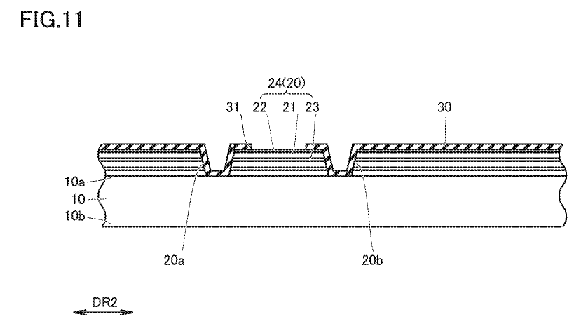

FIG. 11 is a sectional view for illustrating insulating film formation step S4. In insulating film formation step S4, as shown in FIG. 11, insulating film 30 is formed on the side walls of first groove 20a, on the side walls of second groove 20b, on substrate 10 exposed from first groove 20a, on substrate 10 exposed from second groove 20b, and on semiconductor layer 20. In insulating film formation step S4, first, insulating film 30 is deposited by, for example, the CVD method. Second, a resist pattern is formed on the deposited insulating film 30. Third, etching is performed using the above-described resist pattern as a mask, thereby forming an opening 31. First metal layer formation step S5 is performed after insulating film formation step S4.

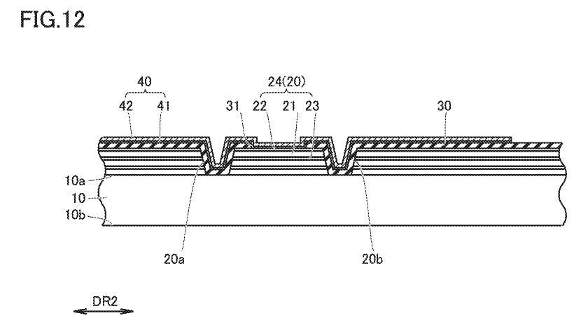

FIG. 12 is a sectional view for illustrating first metal layer formation step S5. As shown in FIG. 12, in first metal layer formation step S5, metal layer 40 is formed on insulating film 30. In first metal layer formation step S5, first, first layer 41 is formed on insulating film 30 by, for example, a vacuum deposition method. Second, an electrolytic plating method is performed using first layer 41 as a base, thereby forming second layer 42. Second metal layer formation step S6 is performed after first metal layer formation step S5.

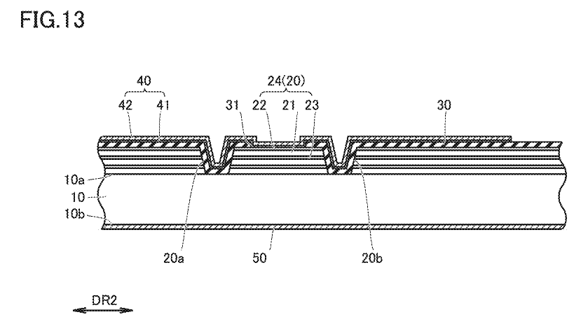

FIG. 13 is a sectional view for illustrating second metal layer formation step S6. As shown in FIG. 13, in second metal layer formation step S6, metal layer 50 is formed on main surface 10b by an appropriate method. Cleavage step S7 is performed after second metal layer formation step S6. In cleavage step S7, substrate 10 and semiconductor layer 20 are cleaved to be divided into a plurality of semiconductor light emitting devices 100. Thus, the structure of semiconductor light emitting device 100 shown in FIGS. 1 to 3 is formed.

### Effects of Semiconductor Light Emitting Device 100

Effects of semiconductor light emitting device 100 will be described below in comparison with a semiconductor light emitting device (semiconductor light emitting device 100A) according to a comparative example.

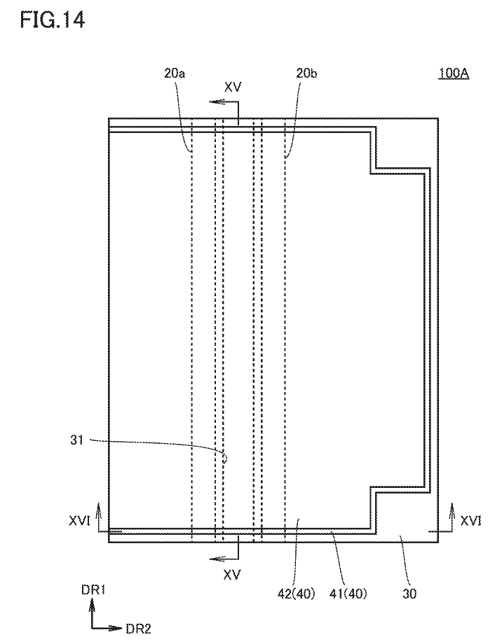

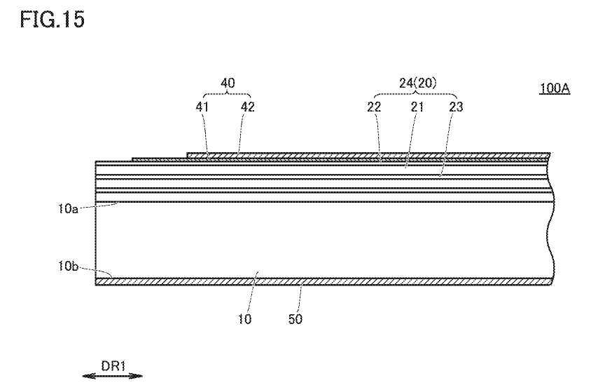

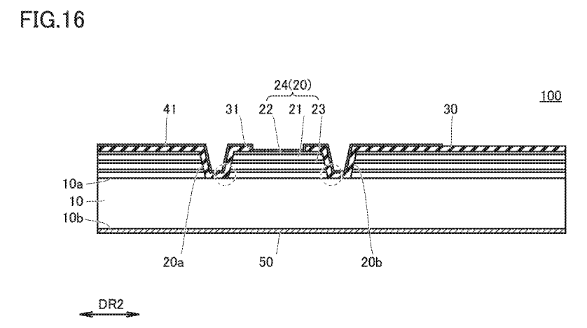

FIG. 14 is a plan view of semiconductor light emitting device 100A. FIG. 15 is a sectional view taken along the line XV-XV in FIG. 14. FIG. 16 is a sectional view taken along the line XVI-XVI in FIG. 14. As shown in FIGS. 14, 15, and 16, in semiconductor light emitting device 100A, the end of first layer 41 in first direction DR1 is located outward of the end of second layer 42 in first direction DR1. Furthermore, in semiconductor light emitting device 100A, the end of opening 31 in first direction DR1 reaches the end of mesa structure 24 in first direction DR1. Except for these points, the configuration of semiconductor light emitting device 100A is common with the configuration of semiconductor light emitting device 100.

In semiconductor light emitting device 100A, a reverse voltage may be applied between metal layer 40 and metal layer 50. Such a reverse voltage occurs, for example, due to undershoot when semiconductor light emitting device 100A is turned off during short-pulse driving.

In semiconductor light emitting device 100A, since the end of first layer 41 in first direction DR1 is located outward of the end of second layer 42 in first direction DR1, the thickness of metal layer 40 is reduced on insulating film 30 located on substrate 10 exposed from the end of first groove 20a (second groove 20b) in first direction DR1. In semiconductor light emitting device 100A, electric field concentration is difficult to relax due to the reduced thickness of metal layer 40, and dielectric breakdown may occur in the portions of insulating film 30 (the portions surrounded by the dotted lines in FIG. 16) on substrate 10 exposed from the end of first groove 20a (second groove 20b) in first direction DR1.

In semiconductor light emitting device 100, a reverse voltage may similarly be applied between metal layer 40 and metal layer 50. However, since the end of first layer 41 in first direction DR1 is located inward of the end of second layer 42 in first direction DR1, compared to semiconductor light emitting device 100A, the thickness of metal layer 40 is not reduced on insulating film 30 located on substrate 10 exposed from the end of first groove 20a (second groove 20b) in first direction DR1. Thus, in semiconductor light emitting device 100, dielectric breakdown of the portion of insulating film 30 on substrate 10 exposed from the end of first groove 20a (second groove 20b) in first direction DR1 is suppressed, leading to improved reverse voltage tolerance.

Note that in semiconductor light emitting device 100A, a protection diode needs to be separately provided because the reverse voltage tolerance is insufficient. Considering that the inductance of the circuit is reduced to drive semiconductor light emitting device 100A with short pulses, the above-described protection diode is disposed near semiconductor light emitting device 100A. As a result, the region where a heat radiation plate can be disposed is narrowed, leading to decreased heat dissipation of semiconductor light emitting device 100A. Contrastingly, in semiconductor light emitting device 100, the above-described protection diode is unnecessary, and a region where a heat radiation plate is disposed can be secured, leading to improved heat dissipation.

When semiconductor light emitting device 100 has a high output, mesa structure 24 having a plurality of light emitting layers 21, or light emitting layer 21 including first n-type cladding layer 21a, second n-type cladding layer 21b, active layer 21c, first p-type cladding layer 21d, and second p-type cladding layer 21e is applied. When such a structure is applied, electric field concentration as described above easily occurs, but in semiconductor light emitting device 100, dielectric breakdown of the portion of insulating film 30 on substrate 10 exposed from the end of first groove 20a (second groove 20b) in first direction DR1 is suppressed even in such a case.

In semiconductor light emitting device 100A, since the end of opening 31 in first direction DR1 reaches the end of mesa structure 24 in first direction DR1, injection of forward current is not limited at the end of mesa structure 24 in first direction DR1. Contrastingly, in semiconductor light emitting device 100, since the end of opening 31 in first direction DR1 is located inward of the end of mesa structure 24 in first direction DR1, injection of forward current is limited at the end of mesa structure 24 in first direction DR1. As a result, in semiconductor light emitting device 100, heat generation near the end of mesa structure 24 in first direction DR1 is suppressed, leading to improved COD.

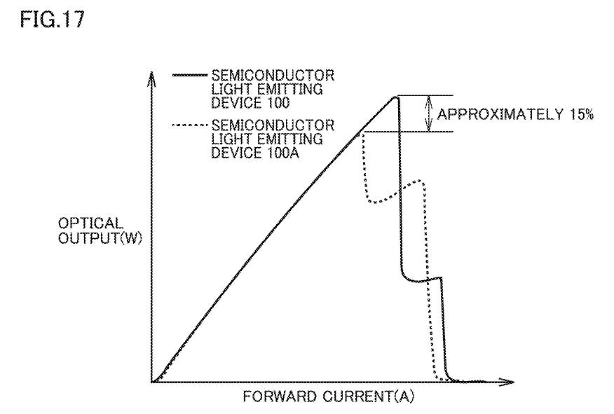

FIG. 17 is a schematic graph showing the relationship between the forward current flowing through mesa structure 24 and the optical output in semiconductor light emitting device 100 and semiconductor light emitting device 100A. The horizontal axis and vertical axis in FIG. 17 indicate forward current (unit: A) and optical output (unit: W), respectively. As shown in FIG. 17, in semiconductor light emitting device 100, COD is improved by approximately 15 % compared to semiconductor light emitting device 100A.

When metal layer 40 is formed thick as a single layer, the cost for forming metal layer 40 increases. In semiconductor light emitting device 100, even when the cost for forming metal layer 40 is reduced by combining a thin first layer 41 and a thick second layer 42, dielectric breakdown of the portion of insulating film 30 on substrate 10 exposed from the end of first groove 20a (second groove 20b) in first direction DR1 is suppressed by disposing the end of first layer 41 in first direction DR1 inward of the end of second layer 42 in first direction DR1.

### Embodiment 2

A semiconductor light emitting device (semiconductor light emitting device 200) according to Embodiment 2 will be described. Here, points different from semiconductor light emitting device 100 will be mainly described, and redundant descriptions will not be repeated.

### Configuration of Semiconductor Light Emitting Device 200

A configuration of semiconductor light emitting device 200 will be described below.

Semiconductor light emitting device 200 includes substrate 10, semiconductor layer 20, insulating film 30, metal layer 40, and metal layer 50. In this regard, the configuration of semiconductor light emitting device 200 is common with the configuration of semiconductor light emitting device 100.

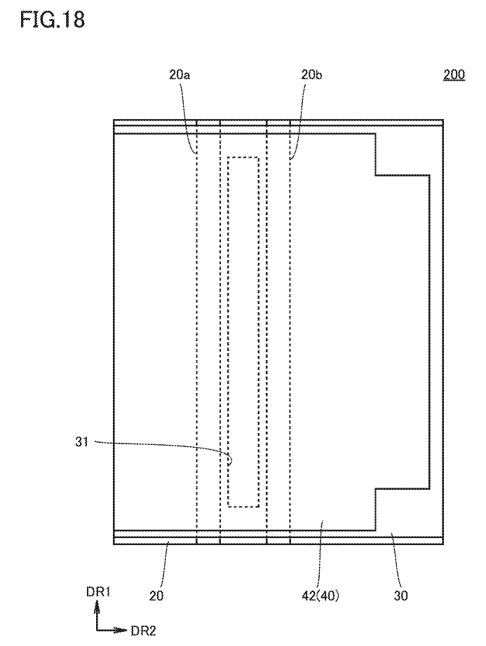

FIG. 18 is a plan view of semiconductor light emitting device 200. As shown in FIG. 18, in semiconductor light emitting device 200, the end of insulating film 30 in first direction DR1 is located inward of the end of mesa structure 24 in first direction DR1. From another viewpoint, the end of semiconductor layer 20 in first direction DR1 is exposed from insulating film 30. In this regard, the configuration of semiconductor light emitting device 200 is different from the configuration of semiconductor light emitting device 100.

### Method of Manufacturing Semiconductor Light Emitting Device 200

A method of manufacturing semiconductor light emitting device 200 will be described below.

The method of manufacturing semiconductor light emitting device 200 includes preparation step S1, semiconductor layer formation step S2, groove formation step S3, insulating film formation step S4, first metal layer formation step S5, second metal layer formation step S6, and cleavage step S7. In this regard, the method of manufacturing semiconductor light emitting device 200 is common with the method of manufacturing semiconductor light emitting device 100.

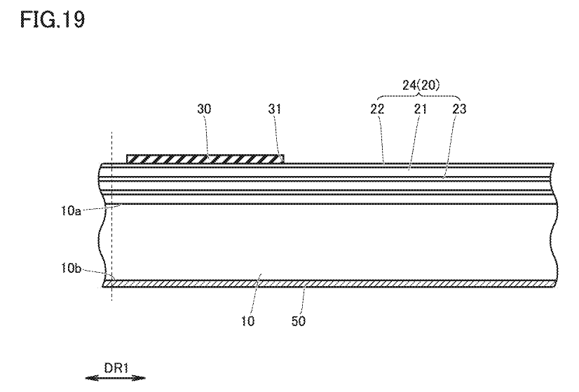

FIG. 19 is a sectional view for illustrating insulating film formation step S4 in the method of manufacturing semiconductor light emitting device 200. The dotted line in FIG. 19 shows the position that indicates the end of mesa structure 24 in first direction DR1. As shown in FIG. 19, in the method of manufacturing semiconductor light emitting device 200, the portion of insulating film 30 near the end of mesa structure 24 in first direction DR1 is removed in insulating film formation step S4. In this regard, the method of manufacturing semiconductor light emitting device 200 is different from the method of manufacturing semiconductor light emitting device 100.

### Effects of Semiconductor Light Emitting Device 200

The effects of semiconductor light emitting device 200 will be described below.

In semiconductor light emitting device 100, insulating film 30 is provided at the cleavage location in cleavage step S7. Contrastingly, in semiconductor light emitting device 200, insulating film 30 at the cleavage location is removed in advance in insulating film formation step S4. Therefore, in semiconductor light emitting device 200, insulating film 30 does not become an obstacle to cleavage step S7, and cleavage step S7 can be easily performed compared to semiconductor light emitting device 100.

### Additional Notes

The above-described embodiments include the following configurations.

### Additional Note 1

A semiconductor light emitting device including:
a substrate;
a semiconductor layer;
an insulating film; and
a metal layer,
wherein the semiconductor layer is disposed on the substrate,
a first groove and a second groove that penetrate the semiconductor layer to expose the substrate are formed in the semiconductor layer, in a plan view,
the first groove and the second groove extend along a first direction and are spaced apart from each other along a second direction perpendicular to the first direction,
the semiconductor layer between the first groove and the second groove forms a mesa structure serving as a light emitting portion,
the insulating film is disposed on the substrate exposed from the first groove and the second groove, on side walls of the first groove, on side walls of the second groove, and on the semiconductor layer,
an opening is formed in the insulating film on the mesa structure,
the metal layer is disposed on the insulating film and is electrically connected to the mesa structure via the opening,
the metal layer includes a first layer and a second layer,
the first layer is disposed on the insulating film,
the second layer is disposed on the first layer, and
an end of the first layer in the first direction is located inward of an end of the second layer in the first direction.

### Additional Note 2

The semiconductor light emitting device according to additional note 1, wherein the end of the second layer in the first direction is located inward of an end of the mesa structure in the first direction.

### Additional Note 3

The semiconductor light emitting device according to additional note 1 or 2, wherein

the opening extends along the first direction, and

an end of the opening in the first direction is located inward of an end of the mesa structure in the first direction.

### Additional Note 4

The semiconductor light emitting device according to additional note 3, wherein a value obtained by dividing a value of COD by a width of the mesa structure in the second direction is 0.95 W/μm or more and 2.0 W/μm or less.

### Additional Note 5

The semiconductor light emitting device according to any one of additional notes 1 to 4, wherein a thickness of the first layer is smaller than a thickness of the second layer.

### Additional Note 6

The semiconductor light emitting device according to any one of additional notes 1 to 5, wherein

the first layer is a vapor deposition layer, and

the second layer is a plating layer.

### Additional Note 7

The semiconductor light emitting device according to any one of additional notes 1 to 6, wherein an end of the insulating film in the first direction is located inward of an end of the mesa structure in the first direction.

### Additional Note 8

The semiconductor light emitting device according to any one of additional notes 1 to 7, wherein

the mesa structure includes at least one light emitting layer and a contact layer disposed on an uppermost layer of the at least one light emitting layer,

each of the at least one light emitting layer includes an active layer, a first n-type cladding layer, a second n-type cladding layer, a first p-type cladding layer, and a second p-type cladding layer,

the first n-type cladding layer is disposed on the second n-type cladding layer,

the active layer is disposed on the first n-type cladding layer,

the first p-type cladding layer is disposed on the active layer, and

the second p-type cladding layer is disposed on the first p-type cladding layer.

### Additional Note 9

The semiconductor light emitting device according to any one of additional notes 1 to 8, wherein the at least one light emitting layer includes a plurality of light emitting layers.

Although the embodiments of the present disclosure have been described as above, various modifications can be made to the above-described embodiments. Furthermore, the scope of the present invention is not limited to the above-described embodiments. The scope of the present invention is defined by the terms of the claims, and is intended to encompass any modifications within the meaning and scope equivalent to the terms of the claims.

### REFERENCE SIGNS LIST

10 substrate; 10a, 10b main surface; 20 semiconductor layer; 20a first groove; 20b second groove; 21 light emitting layer; 21a first n-type cladding layer; 21b second n-type cladding layer; 21c active layer; 21ca first guide layer; 21cb first well layer; 21cc barrier layer; 21ce second guide layer; 21d first p-type cladding layer; 21e second p-type cladding layer; 22 contact layer; 23 tunnel layer; 23a p-type tunnel layer; 23b n-type tunnel layer; 24 mesa structure; 30 insulating film; 31 opening; 40, 50 metal layer; 41 first layer; 42 second layer; 100, 100A, 200 semiconductor light emitting device; DR1 first direction; DR2 second direction; S1 preparation step; S2 semiconductor layer formation step; S3 groove formation step; S4 insulating film formation step; S5 first metal layer formation step; S6 second metal layer formation step; S7 cleavage step.

1. A semiconductor light emitting device comprising:
a substrate;
a semiconductor layer;
an insulating film; and
a metal layer, wherein
the semiconductor layer is disposed on the substrate,
a first groove and a second groove that penetrate the semiconductor layer to expose the substrate are formed in the semiconductor layer,
in a plan view, the first groove and the second groove extend along a first direction and are spaced apart from each other along a second direction perpendicular to the first direction,
the semiconductor layer between the first groove and the second groove forms a mesa structure serving as a light emitting portion,
the insulating film is disposed on the substrate exposed from the first groove and the second groove, on side walls of the first groove, on side walls of the second groove, and on the semiconductor layer,
an opening is formed in the insulating film on the mesa structure,
the metal layer is disposed on the insulating film and is electrically connected to the mesa structure via the opening,
the metal layer includes a first layer and a second layer,
the first layer is disposed on the insulating film,
the second layer is disposed on the first layer, and
an end of the first layer in the first direction is located inward of an end of the second layer in the first direction.

2. The semiconductor light emitting device according to claim 1, wherein the end of the second layer in the first direction is located inward of an end of the mesa structure in the first direction.

3. The semiconductor light emitting device according to claim 1, wherein
the opening extends along the first direction, and
an end of the opening in the first direction is located inward of an end of the mesa structure in the first direction.

4. The semiconductor light emitting device according to claim 3, wherein a value obtained by dividing a value of catastrophic optical damage (COD) by a width of the mesa structure in the second direction is 0.95 W/μm or more and 2.0 W/μm or less.

5. The semiconductor light emitting device according to claim 1, wherein a thickness of the first layer is smaller than a thickness of the second layer.

6. The semiconductor light emitting device according to claim 1, wherein
the first layer is a vapor deposition layer, and
the second layer is a plating layer.

7. The semiconductor light emitting device according to claim 1, wherein an end of the insulating film in the first direction is located inward of an end of the mesa structure in the first direction.

8. The semiconductor light emitting device according to claim 1, wherein
the mesa structure includes at least one light emitting layer and a contact layer disposed on an uppermost layer of the at least one light emitting layer,
each of the at least one light emitting layer includes an active layer, a first n-type cladding layer, a second n-type cladding layer, a first p-type cladding layer, and a second p-type cladding layer,
the first n-type cladding layer is disposed on the second n-type cladding layer,
the active layer is disposed on the first n-type cladding layer,
the first p-type cladding layer is disposed on the active layer, and
the second p-type cladding layer is disposed on the first p-type cladding layer.

9. The semiconductor light emitting device according to claim 8, wherein the at least one light emitting layer includes a plurality of light emitting layers.
